(19) United States
(12) Patent Application Publication
(10) Pub. No.: US 2012/0147915 A1
(43) Pub. Date: Jun. 14, 2012

(54) LASER DIODE AND METHOD OF FABRICATION THE LASER DIODE

(76) Inventors: Piotr Perlin, Warszawa (PL); Marcin Sarzynski, Zabki (PL); Katarzyna Holc, Warszawa (PL); Michal Leszczynski, Mysiadlo (PL); Robert Czernecki, Kalina (PL); Tadeusz Suski, Nowy Prazmow (PL); Michal Bockowski, Warszawa (PL); Izabella Grzegory, Warszawa (PL); Boleslaw Lucznik, Legionowo (PL)

(21) Appl. No.: 13/261,057

(22) PCT Filed: May 22, 2010
(86) PCT No.: PCT/PL2010/050018

§ 371 Date: Feb. 22, 2012

(30) Foreign Application Priority Data
May 30, 2009 (PL) P-388149

(51) Int. Cl. H01S 5/323; H01L 33/14

(52) U.S. Cl. 372/43.01; 438/47; 257/E33.012

(57) ABSTRACT

The laser diode is based on Al In Ga N alloy and consists of: a bottom cladding layer of n-type conductivity, a bottom waveguide layer of n-type conductivity, a light emitting layer, an electron blocking layer of p-type conductivity, an upper waveguide layer of p-type conductivity, an upper cladding layer of p-type conductivity and a subcontact layer, doped with acceptors with concentration level above 10²⁰ cm⁻³. The diode characterizes in that its bottom cladding layer (1) of n-type is made of GaOₓN₁₋ₓ alloy in which x>0.0005. A method of fabricated such laser diode in epitaxial growth of a layer structure consisting of at least a bottom cladding layer of n-type conductivity comprising at least one GaOₓN₁₋ₓ layer (1, 1a, 1c) in which x>0.0005, consisting in that the GaOₓN₁₋ₓ layer (1a, 1c) is fabricated using a high pressure method of nitride solution in gallium at pressure higher than 800 MPa.

### TECHNICAL FIELD

The subject of this invention is a AlInGaN laser diode and a method of fabrication such laser diode.

### BACKGROUND ART

Present-day semiconductor laser diodes are usually fabricated as Separate Confinement Heterostructures, which means that the confinement for carriers and for the optical mode are determined separately by applying materials which differ in refractive index. A sequence of thin semiconductor films is deposited on a monocrystalline substrate, for example on GaAs, InP or GaN. A detail description of the method can be found, for example in: L. A. Coldren, S. W. Corzine, “Diode Lasers and Photonic Integrated Circuits” (Wiley Series in Microwave and Optical Engineering). The active region of such devices consist of quantum wells, bounded by quantum barriers. The electromagnetic mode propagates within the waveguide, which consists of high index layers enclosing the active region and which is then surrounded by low index layers. In the subsequent part of this description “laser waveguide” will be strictly referred to the transversal direction, which is the direction of the structure growth. The electromagnetic mode, or simply the mode will be referred to a specific spatial field distribution, which constitutes a solution to the wave equation in the waveguide. The lateral confinement can be obtained by any other means (index guiding, gain guiding, mesa, buried ridge) without loss of generality of the subsequently given reasoning/arguments. The electron blocking layer does not have to necessarily appear in all of the constructions. In case of lasers based on group III nitrides, emitting light within the spectral range between 400-500 nm, the above mentioned layers are realized using a specific method, which is described, among others, in: S. Nakamura, J. Mater. Res. 14, 2716 (1999) and in the patent publication U.S. Pat. No. 6,838,693 B2. A 50 to 200 μm thick crystalline gallium nitride is used as a substrate. Cladding layers consist of aluminum-gallium nitride, AlₓGa₁₋ₓN, for which x is from 0.05 to 0.12. The thickness of the cladding layers is from 0.5 to 5 μm. The bottom cladding layer is doped with silicon with doping level from 5×10¹⁹ cm⁻³ to 1×10²⁰ cm⁻³. Waveguide layers usually consist of gallium nitride of thicknesses from 0.05 to 0.15 μm. The bottom waveguide can be silicon doped, and the upper waveguide can be magnesium doped. Both waveguide layers may also be undoped. The electron blocking layer is made of AlₓGa₁₋ₓN, where x is from 0 to 0.3. The quantum well layer, in case of lasers emitting in the range of 400-500 nm is made of InₓGa₁₋ₓN, where x ranging from 0 to 0.3 and its thickness ranges from 2 to 10 nm. The upper cladding layer is made of AlₓGa₁₋ₓN, for which x is from 0.09 to 0.35 and its thickness is from 8 to 30 nm. In case of infrared lasers fabricated on a GaAs substrate, the waveguide is made of GaAs layers and AlGaAs cladding layers of high aluminum content. The high aluminum composition ensures the high refractive index contrast between the GaAs-core and the AlGaAs claddings. For example, laser emitting infrared radiation of the wavelength of around 900 nm that uses claddings with 50% aluminum content has the refractive index contrast of around 9% between the GaAs waveguide and AlGaAs claddings. The advantage of the GaAs—AlAs system is that the both compounds have closely matched lattice constants (the difference is only 0.2%). Due to this fact the whole structure can be strain-free. The situation is very different in case of gallium nitride structures. AlGaN, which serves for cladding layers, is lattice-mismatched to gallium nitride substrates (the lattice mismatch between GaN and AlN is of 2.5%). In consequence a strong tensile strain appears in AlGaN layers. If we go beyond a certain value of combination of the layer thickness and composition, a relaxation of strain occurs. This relaxation is realized through macroscopic cracking of the structure and/or generation of misfit dislocations. The maximal thickness and composition of AlGaN can be deduced from literature, for example from the paper: “Elimination of AlGaN epilayer cracking by spatially patterned AlN mask” by Marcin Sarzyński et al. Appl. Phys. Lett. 88, 121124 (2006), according to which obtaining a 40% AlGaN layer of thickness of 1 μm without cracking and other defects is not possible. Additional problem arising in nitride lasers, and which is a consequence of weak vertical confinement of the mode, is the mode leakage into the GaN substrate. Gallium nitride comprises both the waveguide core and the substrate and thus a strong tendency to the leaking of part of the mode into the substrate is observed, which at the same time significantly delimits the Γ factor describing the overlap between the optical mode and the active region. In order to avoid the leakage, the best laser structures are fabricated with thick bottom AlGaN claddings, for example 2 μm thick with 5% AlGaN. From the paper Appl. Phys. Lett. 88, 121124 (2006) a conclusion can be made that such layer would not be cracked, however the amount of elastic energy accumulated in this layer must certainly lead to macroscopic bowing of the whole structure, which has detrimental influence on laser structure processing feasibility.

### Disclosure of Invention

An object of the invention was to fabricate a laser structure featuring better optoelectronic parameters, such as the threshold current and improved structure quality leading to better reliability of the device.

The object is realized through a laser diode based on a AlInGaN alloy. The structure consists of the bottom cladding layer, which has a n-type conductivity, a bottom waveguide layer having also n-type conductivity, a light emitting (active) layer, an electron blocking layer of p-type conductivity, an upper waveguide layer and a subcontact layer, doped with acceptors with concentration level above 10²⁰ cm⁻³. In such diode the bottom cladding layer is made of GaOₓNi₁₋ₓ alloy, where x>0.0005.

In one of variants of the laser diode according to the invention a material of the bottom cladding layer has the refractive index at least one percent smaller (at wavelength of 405 nm) than the refractive index of a material comprising the upper and the bottom waveguide layer.

In another variant of the laser diode according to the invention the bottom cladding layer thickness equals at least 10 μm.

In next variant of the laser diode according to the invention the diode comprises first additional layer not thinner than 0.8 μm, which is made of Al_{y}Ga_{1-y}N, where 0<y<0.1, and which is placed between the bottom cladding layer and the bottom waveguide layer.

In next variant of the laser diode according to the invention the diode comprises two additional layers, the second and the third, which are placed below the bottom cladding layer. The second bottom cladding layer, made of 100 to 400 μm thick gallium nitride, is placed directly below the bottom cladding layer.

The third additional layer, which is made of GaOₓN₁₋ₓ, where x>0.0005, is placed directly below the second additional layer.

In yet another variant of the laser diode according to the invention the second and the third additional layer have dislocation density lower than 1×10⁷ cm⁻².

A fabrication method of a laser diode based on AlInGaN alloy according to the invention relays on epitaxial growth of: a layer structure comprising at least the bottom cladding layer of n-type conductivity having at least one layer of GaOₓN₁₋ₓ, where x>0.0005, a bottom waveguide layer of n-type conductivity, a light emitting layer, an electron blocking layer of p-type conductivity, an upper waveguide layer, an upper cladding layer of p-type conductivity and a subcontact layer doped with acceptors of concentration above 10²⁰ cm⁻³. This method is characterized by a high pressure method of obtaining the GaOₓN₁₋ₓ from a nitride solution in gallium at pressure above 800 MPa.

In one of variants of the method according to the invention, the bottom cladding layer is fabricated as a three layer structure. This structure contains two GaOₓNi₁₋ₓ layers obtained from a nitride solution in gallium using the high pressure method at pressure above 800 MPa, which are grown on the inner gallium nitride layer of thickness of 100 to 400 μm.

In another variant of the method according to the invention, in the fabricated three-layer structure of the bottom cladding layer, the upper GaOₓNi₁₋ₓ layer has thickness from 2 to 100 μm.

The invention entirely eliminates the mode leakage into the substrate, improving the optical confinement factor Γ and also improves the flatness of the surface leading to easier device processing and to a decrease of structural defects in a laser due to reduction of the lattice mismatch between the material of the lower waveguide cladding and the materials of other layers, including waveguide layers.

### BRIEF DESCRIPTION OF DRAWINGS

The invention is presented in the accompanying drawings, where FIG. 1, FIG. 2 and FIG. 3 schematically show three embodiments of the laser structure according to the invention, while

FIG. 4 and FIG. 5 show two optical characteristics of the laser diodes according to the invention.

### MODE FOR CARRYING OUT THE INVENTION

Below have been presented three laser diode structures according to the invention and method of their fabrication.

### Example 1

Laser Diode of Lowered Threshold Current Fabricated on Uniform GaOₓN₁₋ₓ Substrate, Which Was Obtained in the High Pressure Growth Process and of the Structure Presented in FIG. 1.

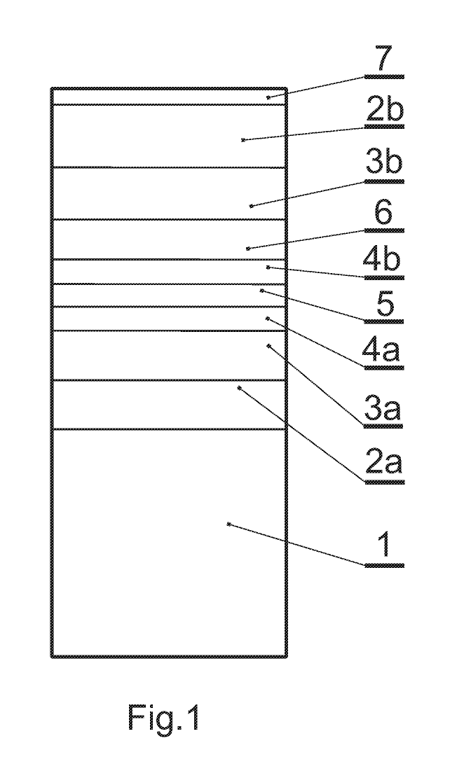

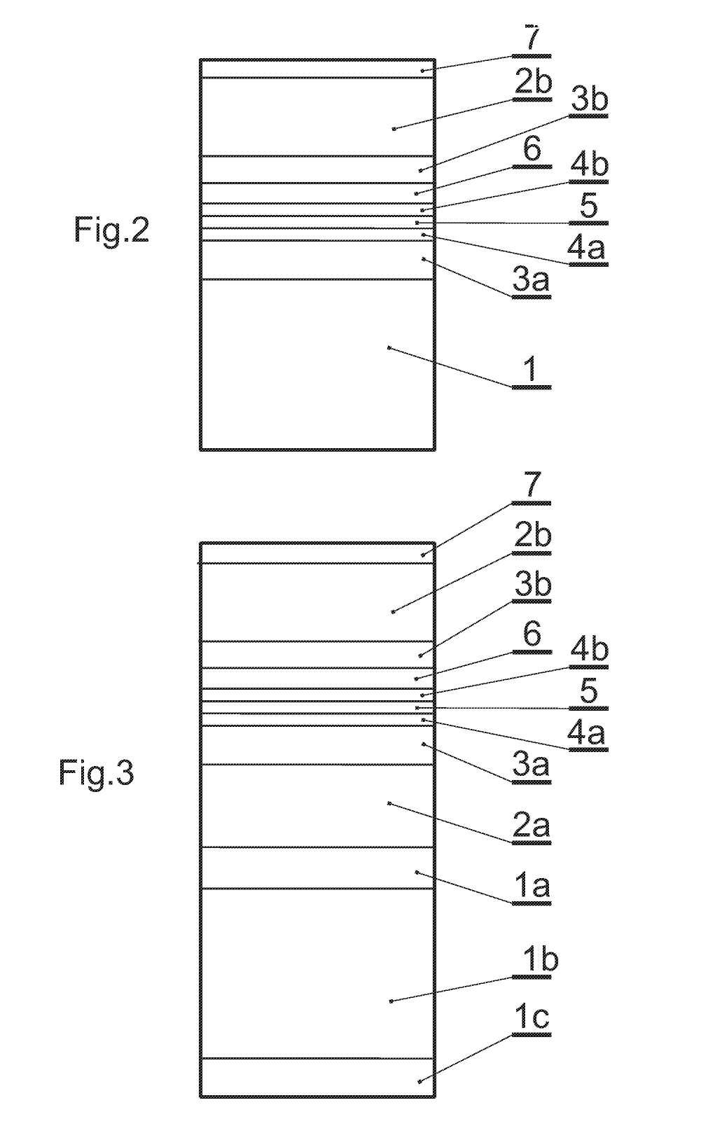

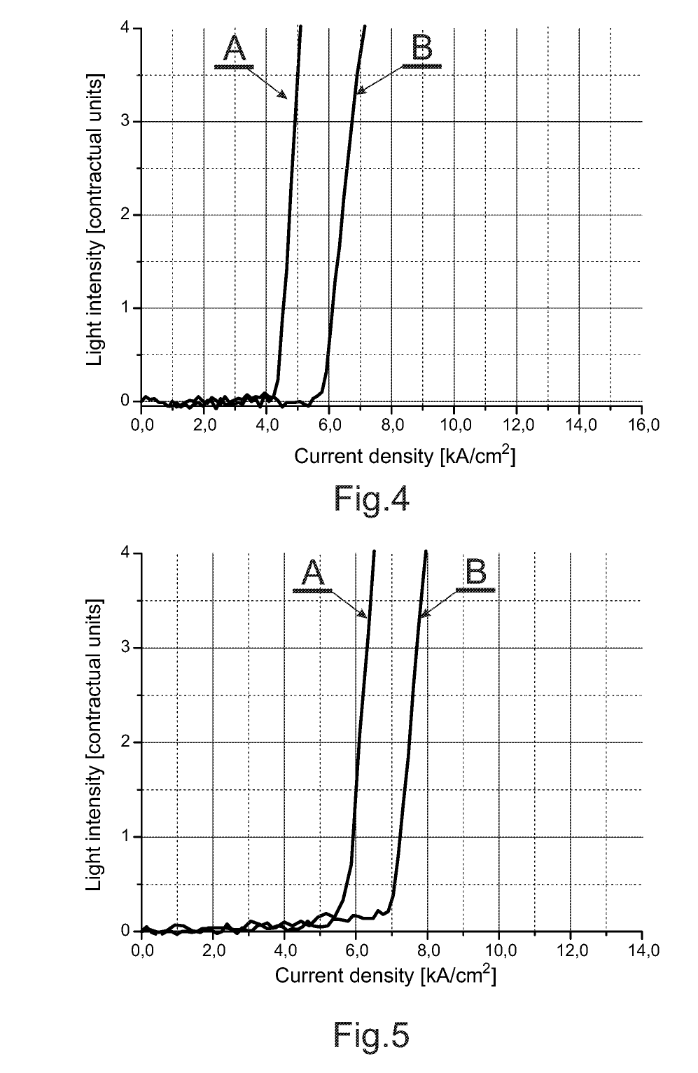

In first step a GaO_{0.0005}N_{0.9995} substrate has been fabricated using the growth method from a nitride solution in gallium under the pressure of 1000 MPa and at temperature of 1500° C. The fabricated crystal has been cut and polished in order to obtain an optically flat platelet of typical thickness of 150-350 μm. The gallium site surface of the crystal, after a proper mechanochemical polishing, featured atomic flatness, visible as atomic steps in the image of the Atomic Force Microscope. The crystal surface was disoriented by at least 0.5 deg. with respect to the crystallografic c axis of the hexagonal Wurzite structure. This substrate is marked in FIG. 1 using reference number 1. Next, the substrate 1 was placed in a MOVPE reactor, where a 600 nm thick Ga_{0.92}Al_{0.08}N layer 2a was grown at temperature about 1050° C. and which was silicon-doped with the level of concentration reaching 5×10¹⁸ cm⁻³. Then, applying the same temperature growth, was fabricated an undoped GaN layer 3a of thickness about 100 nm and serving as the lower caldding layer. After decreasing the temperature to 820° C. the active region with multi quantum wells made of In_{0.1}Ga_{0.9}N/In_{0.01}Ga_{0.99}N, and number of repetition of the multi-quantum-well was three (layers 4a, 5, and 4b have been made three times). Next, after rising the reactor temperature to 1050° C., an 350 nm electron blocking layer 6 of Al_{0.08}Ga_{0.98}N was fabricated. The growth of the structure was terminated in a thin subcontact layer 7 of GaN:Mg with magnesium concentration larger than 10²⁰ cm⁻³. After termination the growth process, the reactor chamber was cooled down in nitrogen ambient. Next, the surfaces of the laser structure were patterned with metallic layers forming contacts to the n- and p-side of the crystal, in such a way that the upper contact was in a shape of a stripe of the length from 300 to 2000 μm and the width from 1 and 100 μm. Annealing of the contacts was performed under temperatures lower than 390° C. The laser can be etched with mesa, which then can be of 300-450 nm high, in order to improve lateral confinement of the electromagnetic mode. Using the GaOₓN₁₋ₓ substrate, the threshold current density has been lowered by about 30% (see FIG. 4, A—laser diode according to the invention, B—a known diode). Have been improved also near and far field patterns which indicate the mode leakage suppresion.

### Example 2

Laser Diode of Lowered Threshold Current Fabricated on Uniform GaOₓN₁₋ₓ Substrate, Which Was Obtained in the High Pressure Growth Process and of the Structure Presented in FIG. 2.

In the first step a substrate 1 of GaOₓN₁₋ₓ was fabricated and prepared in a way described in Example 1. Next, the substrate 1 was placed in a MOVPE reactor, where at temperature about 1050° C. an undoped 100 nm thick layer of GaN forming a lower waveguide layer 3a was fabricated. After decreasing the temperature to 820° C. the active region with multi quantum wells of In_{0.1}Ga_{0.9}N/In_{0.01}Ga_{0.99}N was made, and the number of repetition of the multi-quantum-well was three (layers 4a, 5, and 4b were fabricated three times). Next the reactor temperature was risen to 1050° C. and an electron blocking layer 6 of Al_{0.12}Ga_{0.88}N was fabricated. On the layer 6 an undoped GaN layer forming the upper waveguide 3b was grown. The next layer was the upper cladding layer 2b, which was made of 350 nm thick Al_{0.08}Ga_{0.98}N. The structure growth was terminated in a thin subcontact layer 7 of GaN:Mg with magnesium concentration larger than 10²⁰ cm⁻³. After termination the growth process, the reactor chamber was cooled down in nitrogen ambient. The n- and p-side contacts were fabricated in the same way as described in Example 1. Also in this case the laser can be etched with mesa of 300-450 nm height, in order to improve lateral confinement of the electromagnetic mode.

### Example 3

Laser Diode of Lowered Threshold Current Fabricated on Complex GaOₓN₁₋ₓ Substrate, Which Was Obtained in the High Pressure Growth Process and of the Structure Presented in FIG. 3.

In the first step of the laser diode structure fabrication, a silicon doped GaN crystal with the doping level of 5×10¹⁸ cm⁻³ has been synthesized using HVPE method at temperature of 1050° C. The growth surface of this crystal was prepared in a way described in Example 1 and this substrate was marked in FIG. 3 using reference number 1b. The substrate 1b was introduced into a high pressure reactor chamber, where using the growth method from a nitride solution in gallium under pressure of 1000 MPa and at temperature of 1500° C., on both sides of the HVPE seed GaO_{0.005}N_{0.995} layers were fabricated (layers 1a and 1c). After a mechanochemical polishing of the layers 1a and 1c, the substrate 1 was placed in a MOVPE reactor, where a silicon-doped GaO_{0.92}Al_{0.08}N layer 2a of a thickness of 600 nm was grown at temperature 1050° C. Next, at the same temperature an undoped 100 nm thick GaN layer forming the bottom waveguide 3a was fabricated. After decreasing the temperature to 820° C. the active region with multi quantum wells of In_{0.1}Ga_{0.9}N/In_{0.01}Ga_{0.99}N, and the number of repetition of the multi-quantum-well was three (layers 4a, 5, and 4b were fabricated three times). Next, after rising the reactor temperature to 1050° C. an electron blocking layer 6 of Al_{0.12}Ga_{0.88}N was fabricated, on which subsequently an undoped GaN layer forming the upper waveguide 3b was grown. Next layer was an upper cladding layer 2b, which was made of 350 nm thick Al_{0.08}Ga_{0.98}N. The structure growth was terminated in a thin subcontact layer 7 of GaN:Mg with magnesium concentration larger than 10²⁰ cm⁻³. After termination the growth process, the reactor chamber was cooled down in nitrogen ambient. The n- and p-side contacts were fabricated in the same way as described in Example 1. Also in this case the laser can be etched with mesa of 300-450 nm height, in order to improve lateral confinement of the electromagnetic mode. Using the GaOₓN₁₋ₓ substrate, the threshold current density has been lowered by about 25% (see FIG. 5, A—a laser diode according to the invention, B—a known diode). The improved near and far field patterns indicate the mode leakage suppresion.

1. A laser diode based on AlInGaN alloy, comprising a bottom cladding layer of n-type conductivity, a bottom waveguide layer of n-type conductivity, a light emitting layer, an electron blocking layer of p-type conductivity, an upper waveguide layer of p-type conductivity, an upper cladding layer of p-type conductivity and a subcontact layer, doped with acceptors with concentration level above 10²⁰ cm⁻³, characterized in that the bottom cladding layer of n-type is made of GaOₓN₁₋ₓ alloy, in which x>0.0005.

2. The laser diode according to claim 1, characterized in that a material of the bottom cladding layer (1) possess the refractive index at least one percent lower (at the wavelength of 405 nm) than the refractive index of a material constituting the bottom (3a) and the upper (3b) waveguide layer.

3. The laser diode according to claim 1, characterized in that thickness of the bottom cladding layer (1) is at least 10 μm.

4. The laser diode according to claim 1, characterized in that it comprises a first additional layer (2a) of thickness not smaller than 0.8 μm,
made of Al_{y}Ga_{1-y}N alloy for which 0<y<1, and situated between the bottom cladding layer (1) and the bottom waveguide layer (2).

5. The laser diode according to claim 1, characterized in that it comprises two additional layers, the second (1a) and the third (1c), situated
below the bottom cladding layer (1), and in that directly under the bottom cladding layer (1) the second additional layer (1a) of a gallium nitride seed of the thickness of 100 to 400 μm is located while directly underneath there is the third additional layer (1c) of 2 to 100 μm thick GaOₓN₁₋ₓ, in which x>0.0005.

6. The laser diode according to claim 5, characterized in that the second additional layer (1a) and the third additional layer (1c) have dislocation densities lower than 1×10⁷ cm⁻².

7. A method of fabricating a laser diode based on AlInGaN alloy, consisting in epitaxial growth of a layer structure consisting of at least one bottom cladding layer of n-type conductivity comprising at lest one GaOₓNi.ₓ layer (1, 1a, 1c) in which x>0.0005, a bottom waveguide layer of n-type conductivity, a light emitting layer, an electron blocking layer of p-type conductivity and an acceptor-doped subcontact layer with concentrations above 10²⁰ cm⁻³, characterized in that the GaOₓN₁₋ₓ layer (1a, 1c) is fabricated using a high pressure method of nitride solution in gallium at pressures of 800 MPa.

8. The method according to claim 7, characterized in that the bottom cladding layer (1a, 1b, 1c) is fabricated as three layer structure comprising two layers (1a, 1c) of GaOₓN₁₋ₓ deposited on the middle (inner) layer (1b) of gallium nitride of thickness of 100 to 400 μm, using a high pressure method of nitride solution in gallium at pressures of 800 MPa.

9. The method according to claim 8, characterized in that the fabricated three layer structure of the bottom cladding layer (1a, 1b, 1c) the upper layer (1a), made of GaOₓN₁₋ₓ is at least 10 μm thick, and the bottom layer (1c), made of GaOxNi.ₓ is of 2 to 100 μm thick.
